(19) United States
(12) Patent Application Publication
(10) Pub. No.: US 2025/0192725 A1
(43) Pub. Date: Jun. 12, 2025

(54) LOAD MODULATING LOOP COMBINER FOR LINEAR POWER AMPLIFIER

(71) Applicant: THE REGENTS OF THE UNIVERSITY OF COLORADO, A BODY CORPORATE, Denver, CO (US)

(72) Inventors: Taylor Wallis BARTON, Boulder, CO (US); William SEAR, Aurora, CO (US)

(21) Appl. No.: 18/840,796

(22) PCT Filed: Feb. 23, 2023
(86) PCT No.: PCT/US2023/063099

§ 371 Date: Aug. 22, 2024

Related U.S. Application Data
(60) Provisional application No. 63/313,099, filed on Feb. 23, 2022.

(51) Int. Cl. H03F 1/02; H03F 1/32; H03F 1/56; H03F 3/21

(52) U.S. Cl. CPC H03F 1/0288; H03F 3/211; H03F 1/3223; H03F 1/565

(57) ABSTRACT

A load modulating loop combiner comprises a first coupler configured to couple a signal from an upper pathway to a lower pathway. A main amplifier is configured to receive the signal on the upper pathway. The main amplifier is connected to a first port of a three-port, non-isolating coupling structure. A first phase delay is configured to receive the signal that was coupled to the lower pathway. The first phase delay is connected to a summing junction. The summing junction is connected to a second port of the three-port, non-isolating coupling structure through a second phase delay. An output of the summing junction is connected to an input of an auxiliary amplifier. A third port on the three-port, non-isolating coupling structure is connected to an output of the auxiliary amplifier.

### CROSS-REFERENCE TO RELATED APPLICATIONS

This application claims the benefit of and priority to U.S. Provisional Patent Application Ser. No. 63/313,099 filed on 23 Feb. 2023 and entitled “LOAD MODULATING LOOP COMBINER FOR LINEAR POWER AMPLIFIER,” which application is expressly incorporated herein by reference in its entirety.

### GOVERNMENT RIGHTS

This invention was made with government support under grant number 1846507 awarded by the National Science Foundation. The government has certain rights in the invention.

### BRIEF SUMMARY

Disclosed embodiments comprise a load modulating loop combiner. The load modulating loop combiner comprises a first coupler configured to couple a signal from a upper pathway to a lower pathway. A main amplifier is configured to receive the signal on the upper pathway. The main amplifier is connected to a first port of a three-port, non-isolating coupling structure. A first phase delay is configured to receive the signal that was coupled to the lower pathway. The first phase delay is connected to a summing junction. The summing junction is connected to a second port of the three-port, non-isolating coupling structure through a second phase delay. An output of the summing junction connects to an input of an auxiliary amplifier. A third port on the three-port, non-isolating coupling structure connects to an output of the auxiliary amplifier.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings described below.

FIG. 1 illustrates an example architecture of a Load Modulating Loop Combiner (LMLC).

FIG. 2 illustrates an example architecture of an LMLC using a combined non-isolating combiner/coupled line coupler structure.

FIG. 3 illustrates a chart showing simulated and measured data.

FIG. 4 illustrates a chart showing simulated and measured data.

FIG. 5 illustrates a chart showing measured data.

### DETAILED DESCRIPTION

Within the analog linearization design space, some of the best performance improvement is achieved through the use of feedforward amplifier (FFA) technology. Compared to other types of power amplifiers (PAS) the FFA suffers from lower efficiency and output power operation, albeit with the benefit of lower output distortion. The two loops in conventional feedforward structures, the signal cancellation loop and error cancellation loop, have been implemented using directional couplers; i.e. without feedback interaction between the injected feedforward signal and the main PA. As used herein, a power amplifier may also be described as simply an “amplifier.”

The FFA may have a superficial resemblance to that of the Doherty PA (DPA), except that the DPA employs a feedback-like interaction between the main and auxiliary PAs to produce load modulation. Load modulation is a type of PA architecture that utilize two or more devices to perturb the fundamental impedance presented to the drain of one (or all) devices such that the efficiency in power back off is improved compared to the single-ended component PAs. In the case of the DPA an auxiliary amplifier and main amplifier (sometimes called the “carrier” and “peaking” amplifiers) are connected together through a non-isolating “Doherty combiner.” In the conventional DPA at low power levels the auxiliary amplifier is biased off and appears to present an open circuit, which will result in the main amplifier seeing twice its optimal termination impedance (2Ropt), meaning the amplifier will reach its peak efficiency at half its maximum voltage swing, or 6 dB down from peak output power. Above this half voltage swing point the auxiliary amplifier will begin to conduct and present a progressively smaller impedance as the output power increases. At the peak output power both the main and auxiliary amplifiers will be presented by the optimal fundamental drain impedance Ropt, and the main amplifier will again reach its peak efficiency. Between those two peaks the efficiency will remain high, albeit smaller than the peak efficiency of the main.

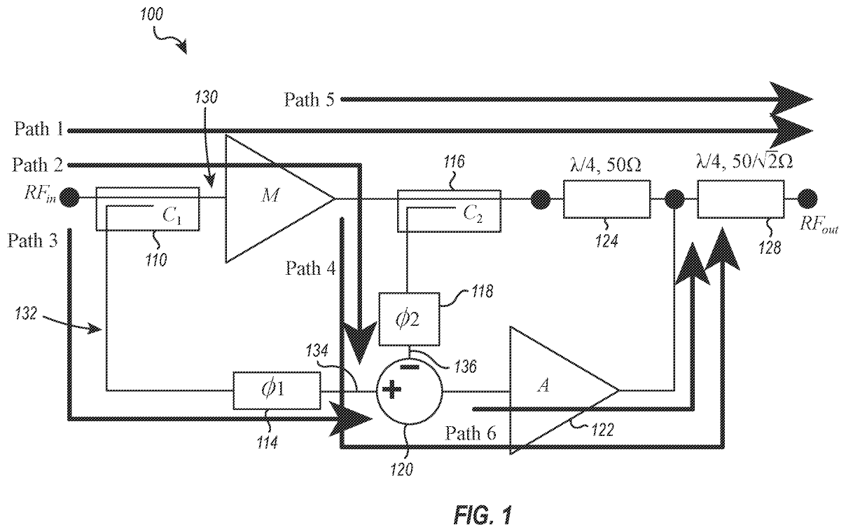

Disclosed embodiments includes a load-modulated loop combiner (LMLC) 100 PA architecture, shown in block diagram form in FIG. 1. The LMLC 100 is configured to produce modulation on at least one component device. In the LMLC 100 a single auxiliary PA 122 simultaneously provides load modulation and distortion cancellation functions. The LMLC 100 draws from the feedforward architecture in that it has a dual-loop structure, but with a non-directional summing junction at the output stage.

In at least one embodiment, the LMC may be designed to operate with a non-isolating coupling structure 116 based on a quarter wavelength line with offset lines such that the Main 20) amplifier 112 and Auxiliary amplifier 122 interact. The interaction of the Main amplifier 112 and Auxiliary amplifier 122 is selected such that the impedance looking into the combiner seen by the Main amplifier 112 decreases when the Auxiliary amplifier 122 turns on which maximizes the efficiency of the overall amplifier over a wide dynamic range of powers.

To control the behavior of the fundamental signal and distortion products simultaneously, the LMLC comprises four tuning elements: a first phase delay line ϕ₁ 114, a second phase delay line ϕ₂ 118 and the coupling factors of a first coupler C₁ 110 and a second coupler C₂ 116. As used herein, the second coupler C₂ 116 may more specifically comprise a three-port, non-isolating coupling structure 116, as such the two terms may be used interchangeably herein. In at least one embodiment, the three-port, non-isolating coupling structure 116 comprises one or more of a variety of different coupling structures, including at least a coupled line structure.

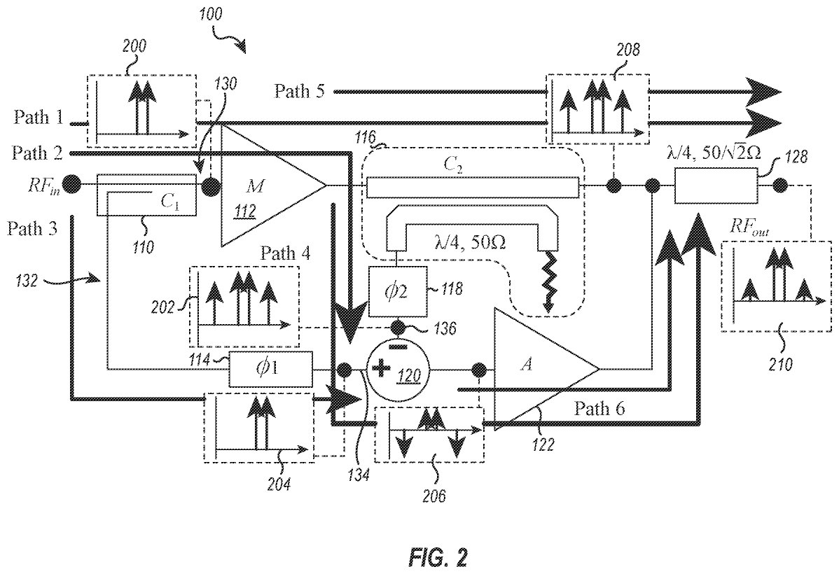

The tuning elements are chosen to control the response through the six signal paths shown in both FIG. 1 and FIG. 2 such that paths 4 and 5 are equal in amplitude and opposite in phase to maximize distortion cancellation and the vector sum of paths 2 and 3 plus path 4 has equal phase delay to path 1 to produce load modulation. Paths 1 and 2 must also be selected such that the amplitude of the fundamental signal arriving at the input of the auxiliary amplifier 122 changes correctly with the input signal for load modulation. Each block x in FIG. 2 is described in terms of the associated gain Aₓ, coupled gain Cₓ (if appropriate), and phase shift θₓ.

The first phase delay line ϕ₂ 118 and coupling of second coupler C₂ 116 directly control path 4, which may be adjusted to have equal amplitude and 180 degree phase difference from path 3 in order cancel the distortion products generated by the main amplifier 112 at the output. To match the amplitude of these two paths, the second coupler C₂ 116 may be selected to have gain A_{C2}, written in terms of the gains (A_{C2}, A_{ϕ1}, A_{A}) of the through path of second coupler C₂ 116, the first delay line ϕ₁ 114, and the voltage gain of the auxiliary amplifier 122 as:

$${C}_{{C}_{2}} = \frac{{A}_{{C}_{2}}}{{A}_{A} {A}_{{ϕ}_{1}}} \qquad Equation 1$$

In Equation 1, the gain (A_{ϕ1}) of the first delay line ϕ₁ 114 can be approximated as 1, which means that the coupling factor of the second coupler C₂ 116 should be selected to be approximately equivalent to the gain of the auxiliary amplifier 122. This selection of the coupling factor of the second coupler C₂ 116 may be consistent with how the second coupler C₂ 116 is designed in the conventional feedforward architecture.

The second phase delay line ϕ₂ 118 may be selected such that path 4 and path 5 are 180 degrees out of phase from each other, again to ensure cancellation. Assuming that the summing junction 120 (in this case a subtractor) shown in FIG. 2 is ideal, this results in the following phase requirement for the second delay line ϕ₂ 118:

$${θ}_{{ϕ}_{2}} = ( {θ}_{{A}_{C 2}} - {θ}_{{C}_{C 2}} ) - {θ}_{A} \qquad Equation 2$$

Of note, selection of the second delay line ϕ₂ 118 and the second coupler C₂ 116 can also perturb the fundamental signal component presented to the auxiliary amplifier 122, which may adversely affect the load modulation. Conveniently, the first delay line ϕ₁ 114 and the first coupler C₁ 110 only affect the fundamental signal component, and can be selected so that the correct fundamental signal drives the auxiliary amplifier 122. The coupling factor (C_{C1}) of the first coupler C₁ 110 and phase delay (θ_{ϕ1}) of the first delay line ϕ₁ 114 can be selected such that the magnitude of the fundamental signal applied to the input of the auxiliary amplifier 122 is an appropriately scaled copy of the input signal. At the fundamental frequency, the input signal to the auxiliary amplifier is the vector sum of the signals from paths 2 and 3, so both amplitude and phase of both signal paths control the overall amplitude and phase of the input signal to the auxiliary amplifier 122. The combined amplitude and phase dependence are removed by setting the phase through paths 2 and 3 plus the additional delay in path 6 to be equal to the delay in path 1, such that the fundamental signals through the main amplifier 112 and auxiliary amplifier 122 are correctly phase aligned such that load modulation occurs. This condition is met when the phase delays through paths 2 and 3 are equal (a consequence of the previous selection of θ_{ϕ2} in (2)) resulting in the following phase requirement for the first delay line ϕ₁ 114:

$${θ}_{{ϕ}_{1}} = ( {θ}_{{A}_{C 1}} - {θ}_{{C}_{C 1}} ) + ( {θ}_{M} - {θ}_{A} ) + {θ}_{{A}_{{C}_{2}}} \qquad Equation 3$$

With the phase delay for the first delay line ϕ₁ 114 determined from Equation 3 the coupling factor of the first coupler C₁ 110 can be selected so that the fundamental signal presented to the input of the auxiliary amplifier 122 is a copy of the input being presented to the main amplifier 112 in Equation 4.

$${C}_{{C}_{1}} = \pm \frac{{( {A}_{M} {C}_{{C}_{2}} {A}_{{ϕ}_{2}} )}^{2} + 1}{\sqrt{{( {A}_{M} {C}_{{C}_{2}} {A}_{{ϕ}_{2}} )}^{4} + 6 {( {A}_{M} {C}_{{C}_{2}} {A}_{{ϕ}_{2}} )}^{2}} + 1} \qquad Equation 4$$

The expression in Equation 4 at first appears to be complicated, but assuming the loss (A_{ϕ2}) of second delay line ϕ₂ 118 is small and that the gain (A_{M}) of the main amplifier 112 and coupling factor (C_{C2}) of the second coupler C₂ 116 are equal and opposite in magnitude (a condition met when A_{M}≈A_{A}), the coupling factor of the first coupler C₁ 110 simplifies to around 6 dB.

In one example embodiment, a 3.5 GHz prototype design uses identical main and auxiliary PA networks based on the CG2H40010 device from Wolfspeed. The auxiliary amplifier is be biased into class-C while the main amplifier operates in deep class-AB. Under these biasing conditions the LMLC design constraint from (4) that A_{M}≈A_{A} is satisfied after the auxiliary amplifier has turned on and the main amplifier has begun to compress, corresponding to the region where distortion reduction will be most valuable.

The second coupler C₂ and the 50-Ω λ/4 of the non-isolating output combiner can be conveniently mixed into a single coupled line coupler structure as shown in FIG. 2 because the coupled line coupler has a through phase delay of λ/4. In the example implementation the coupled line segment is shorter than λ/4 for practical considerations of the interconnection with the auxiliary amplifier while maintaining the correct through phase shift, and the coupler is designed to have a coupling factor of 16 dB (equal to the gain expected from the main amplifier as in Eqn. 1). Finally, the subtractor element is implemented as a rat-race combiner whose size is optimized to connect the input of the auxiliary amplifier and output of the coupled line coupler with the appropriate phase delay. In the experimental setup, the coupling factor C₁ and phase delay τ₁ are implemented digitally using a dual drive to allow for tuning. In a future realization the fixed amplitude/phase relationship between the two inputs is straightforward to implement using a passive structure.

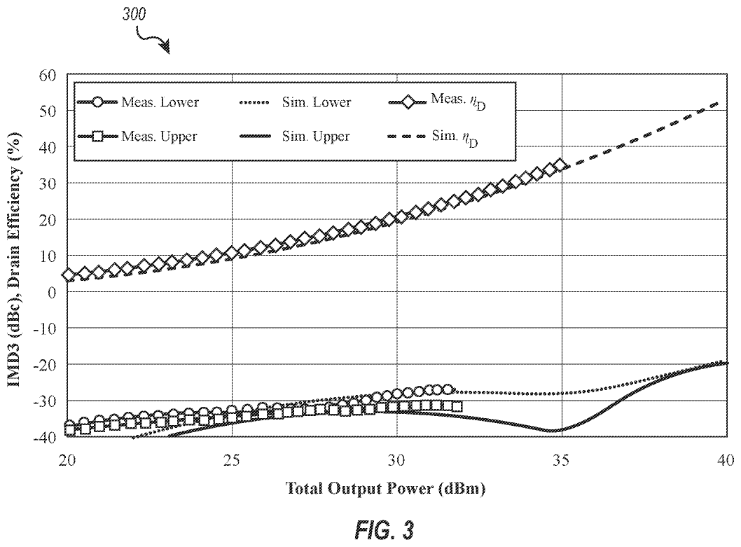

The LMLC prototype is measured using the dual-drive test setup described in Section III with CW and two-tone signal excitations. With C₁=6 dB and τ₁=240° the simulated and measured CW drain efficiency (η_{D}) and 10 MHz two-tone IMD3 is captured in the chart 300 of FIG. 3.

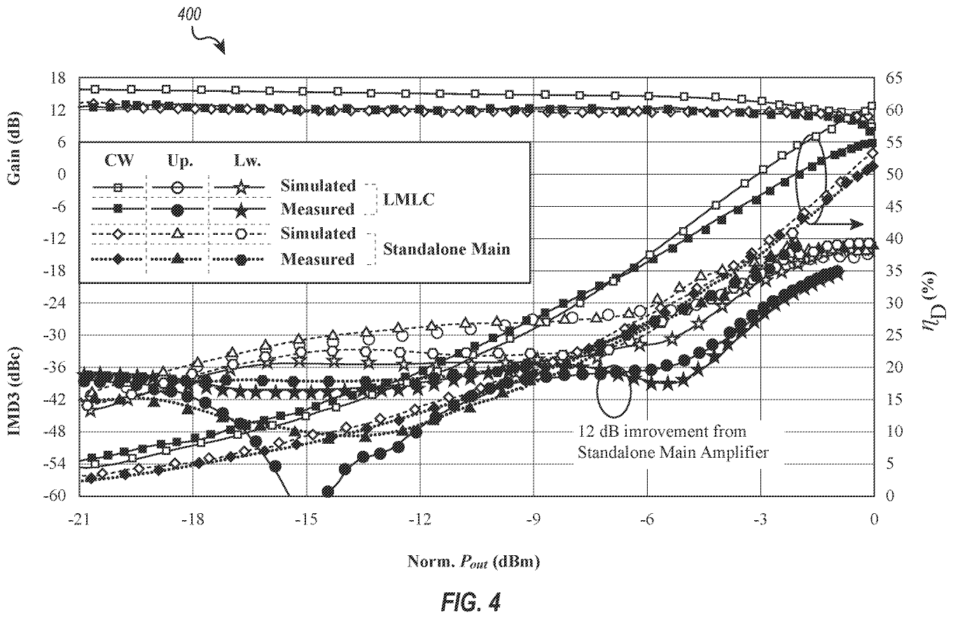

An example LMLC prototype and standalone main PA were measured using under CW, two-tone, and modulated signal excitations. With C_{C1}=6 dB and θ_{ϕ1}=330° the simulated and measured CW gain, CW drain efficiency (η_{D}), and 10 MHz two-tone IMD3 is captured in FIG. 4. As such, FIG. 4 depicts a chart 400 of simulated and measured CW gain, CW drain efficiency, and 10 MHz IMD3 response of an example LMLC and its standalone main amplifier centered at 3.5 GHZ. In this example, the LMLC reaches a peak CW output power of 42 dBm and the standalone main amplifier has a peak CW output power of 40 dBm. The general response of the LMLC for both the measured CW and two-tone responses is consistent with the simulated performance, although the measured drain efficiency is lower than simulated at high output power, likely due to the turn-on characteristics of the auxiliary PA. The measured 10 MHz IMD3 of the LMLC is 3-30 dB lower than simulated, most likely due to on-board tuning of the IF impedance presented to the drain of the main PA. The feedforward action is evident when compared to the standalone main PA above 9 dB back-off from peak output power, although the standalone main has lower peak efficiency than the LMLC because it is not optimized for a 50Ω output termination.

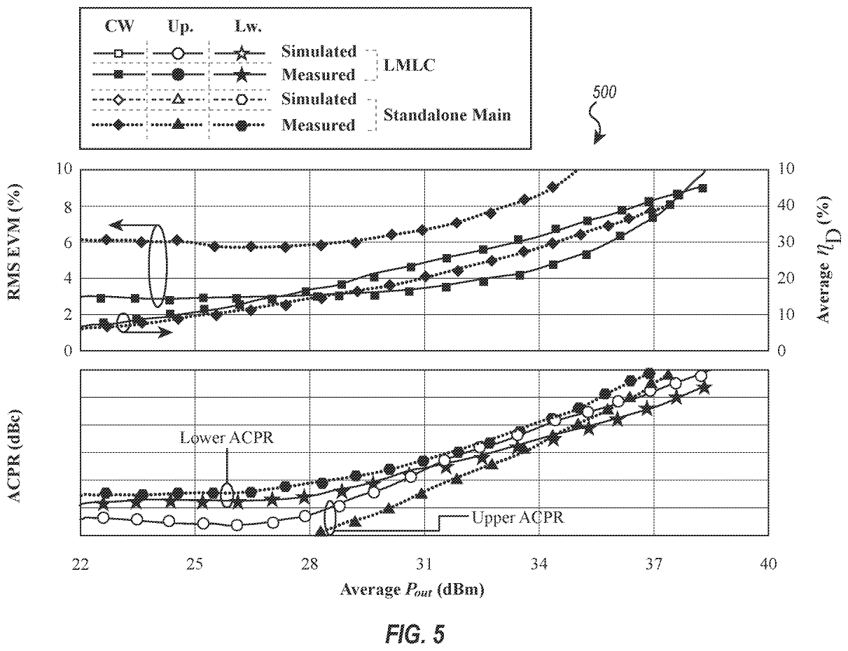

As shown in the chart 500 of FIG. 5, when excited by a 10 dB peak to average power ratio (PAPR) 100 MHz LTE-like signal, the LMLC maintains an RMS EVM below 3% until 28 dBm average output power while the adjacent channel power ratio (ACPR) remains below −35 dBc with a 17% average drain efficiency. This is an improvement over conventional main amplifiers and DPA which reach −35 dBc ACPR at 24 dBm average output power for a 5 MHz wide LTE signal.

Additional, embodiments to the LMLC 100 disclosed herein include at least (1) adding additional control loops that combine at the RF Output of the structure, (2) controlling gain response (compression or expansion) of the overall amplifier, (3) controlling a noise figure of overall amplifier, (4) adaptive control (digital or analog) of the ϕ₁ element, (5) adaptive control (digital or analog) of the ϕ₂ element, (6) adaptive control (digital or analog) of the coupling factor of coupler C₁, (7) adaptive control (digital or analog) of the coupling factor of coupler C₂, (8) adaptive control (digital or analog) of the coupling factor/phase of the output combiner, (9) adaptive control (digital or analog) of the Main Amplifier Gain and/or Phase, (10) adaptive control (digital or analog) of the Auxiliary Amplifier Gain and/or Phase, and/or (11) other similar modifications and improvements.

Disclosed embodiments include an LMLC 100 that comprises a first coupler 110 configured to couple a signal from an upper pathway 130 to a lower pathway 132. As used herein, “upper” and “lower” are used for ease of description with respect to the figures. One of skill in the art will appreciate that in practice the pathways may be otherwise arranged and still fall within the scope of this description. A main amplifier 112 is configured to receive the signal on the upper pathway 130. The main amplifier 112 is also connected to a first port of a three-port, non-isolating coupling structure 116. In at least one embodiment, the three-port, non-isolating coupling structure 116 comprises a 90-degree phase delay.

A first phase delay line 114 is configured to receive the signal that was coupled to the lower pathway 132. The first phase delay line 114 is connected to a first port 134 of a summing junction 120. As used herein, the summing junction 120 may comprise either an adder or a subtractor. The second input port 136 of the summing junction may be connected to a second port of the three-port, non-isolating coupling structure 116 through a second phase delay line 118.

An output of the summing junction 120 may be connected to an input of an auxiliary amplifier 122. A third port on the three-port, non-isolating coupling structure 116 may connect to an output of the auxiliary amplifier 122. In at least one embodiment the main amplifier 112 and the auxiliary amplifier 122 comprise different gains and/or different peak power levels. Additionally or alternatively, one or more circuit components, such a phase delay line 124, may be positioned between the three-port, non-isolating coupling structure 116 and the output of the auxiliary amplifier 122. An impedance inverter, such as a phase delay line 128 may be positioned at the output of the LMLC 100.

When designing the LMLC 100, the components may be designed such that a first phase delay on the upper pathway 130 between an input to the first coupler 110 and a second port 136 of the summing junction 120 is substantially equal to a second phase delay on the lower pathway 132 between the input to the first coupler and a first port 134 of the summing junction. Additionally or alternatively, when designing the LMLC 100, the components may be designed such that the second phase delay line 118 and a coupling of the three-port, non-isolating coupling structure 116 are configured to provide the signal on the upper pathway 130 with substantially equal amplitude and a 180 degree phase difference from the signal on the lower pathway 132 at the summing junction 120. Additionally or alternatively, the first coupler 110 and the first phase delay line 114 are configured to provide the signal on the lower pathway 132 with substantially equal amplitude and a 180 degree phase difference from the signal on the upper pathway 130 at the summing junction 120.

FIG. 2 depicts various example signals 200, 202, 204, 206, 208, 210 at different points within the LMLC 100. The example signals show two signals in the middle that represent the desired data signal and two signals on the sides that represent distortion, or noise. The distortion is often added by amplifiers and other non-linear circuit components. As depicted by the example signals, the lower pathway 132 is able to create inverted copies of the distortions and then cancel, or substantially reduce, the distortions in the signal on the upper pathway 130.

The novel LMLC architecture simultaneously produces load modulation and distortion product cancellation in a form factor that can enable higher performance 5G communications networks. A proof-of-concept first-pass design performs well in terms of both efficiency and linearity, without the additional signal processing complexity found in current state-of-the art RF power amplifiers. A complete design methodology is presented and validated that enables systematic linear efficient PA design without requiring extensive modeling or optimization of nonlinear PA behaviors.

The discussion herein refers to a number of methods and method acts that may be performed. Although the method acts may be discussed in a certain order or illustrated in a flow chart as occurring in a particular order, no particular ordering is required unless specifically stated, or required because an act is dependent on another act being completed prior to the act being performed.

When the terms “about,” “approximately,” “substantially,” or the like are used in conjunction with a stated amount, value, or condition, it may be taken to mean an amount, value or condition that deviates by less than 20%, less than 10%, less than 5%, less than 1%, less than 0.1%, or less than 0.01% of the stated amount, value, or condition.

Further, the methods may be practiced by a computer system including one or more processors and computer-readable media such as computer memory. In particular, the computer memory may store computer-executable instructions that when executed by one or more processors cause various functions to be performed, such as the acts recited in the embodiments.

Computing system functionality can be enhanced by a computing systems' ability to be interconnected to other computing systems via network connections. Network connections may include, but are not limited to, connections via wired or wireless Ethernet, cellular connections, or even computer to computer connections through serial, parallel, USB, or other connections. The connections allow a computing system to access services at other computing systems and to quickly and efficiently receive application data from other computing systems.

Disclosed embodiments may comprise or utilize a special purpose or general-purpose computer including computer hardware, as discussed in greater detail below. Disclosed embodiments also include physical and other computer-readable media for carrying or storing computer-executable instructions and/or data structures. Such computer-readable media can be any available media that can be accessed by a general purpose or special purpose computer system. Computer-readable media that store computer-executable instructions are physical storage media. Computer-readable media that carry computer-executable instructions are transmission media. Thus, by way of example, and not limitation, embodiments of the invention can comprise at least two distinctly different kinds of computer-readable media: physical computer-readable storage media and transmission computer-readable media.

Physical computer-readable storage media includes RAM, ROM, EEPROM, CD-ROM or other optical disk storage (such as CDs, DVDs, etc.), magnetic disk storage or other magnetic storage devices, or any other medium which can be used to store desired program code means in the form of computer-executable instructions or data structures and which can be accessed by a general purpose or special purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmissions media can include a network and/or data links which can be used to carry program code in the form of computer-executable instructions or data structures and which can be accessed by a general purpose or special purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A load modulating loop combiner comprising:
a first coupler configured to couple a signal from an upper pathway to a lower pathway;
a main amplifier configured to receive the signal on the upper pathway, the main amplifier connected to a first port of a three-port, non-isolating coupling structure;
a first phase delay line configured to receive the signal that was coupled to the lower pathway, the first phase delay line connected to a summing junction;
the summing junction connected to a second port of the three-port, non-isolating coupling structure through a second phase delay line; and
an output of the summing junction connected to an input of an auxiliary amplifier.

2. The load modulating loop combiner as recited in claim 1, further comprising a third port on the three-port, non-isolating coupling structure connected to an output of the auxiliary amplifier.

3. The load modulating loop combiner as recited in claim 1, wherein the three-port, non-isolating coupling structure comprises a coupled line structure.

4. The load modulating loop combiner as recited in claim 1, wherein the summing junction comprises a subtractor.

5. The load modulating loop combiner as recited in claim 1, wherein the summing junction comprises an adder.

6. The load modulating loop combiner as recited in claim 1, wherein the load modulating loop combiner is configured to produce modulation on at least one component device.

7. The load modulating loop combiner as recited in claim 1, wherein the main amplifier and the auxiliary amplifier comprise different gains.

8. The load modulating loop combiner as recited in claim 1, wherein the main amplifier and the auxiliary amplifier comprise different peak power levels.

9. The load modulating loop combiner as recited in claim 1, wherein the three-port, non-isolating coupling structure comprises a 90 degree phase delay.

10. The load modulating loop combiner as recited in claim 1, wherein a first phase delay between an input to the first coupler and a second port of the summing junction is substantially equal to a second phase delay between the input to the first coupler and a first port of the summing junction.

11. The load modulating loop combiner as recited in claim 10, wherein the second phase delay line and a coupling of the three-port, non-isolating coupling structure are configured to provide the signal on the upper pathway with substantially equal amplitude and a 180 degree phase difference from the signal on the lower pathway at the summing junction.

12. The load modulating loop combiner as recited in claim 11, wherein the first coupler and the first phase delay line are configured to provide the signal on the lower pathway with substantially equal amplitude and a 180 degree phase difference from the signal on the upper pathway at the summing junction.

13. The load modulating loop combiner as recited in claim 1, wherein the second phase delay line and a coupling of the three-port, non-isolating coupling structure are configured to provide the signal on the upper pathway with substantially equal amplitude and a 180 degree phase difference from the signal on the lower pathway at the summing junction.

14. The load modulating loop combiner as recited in claim 1, wherein the first coupler and the first phase delay line are configured to provide the signal on the lower pathway with substantially equal amplitude and a 180 degree phase difference from the signal on the upper pathway at the summing junction.
